(19) United States
(12) Patent Application Publication
(10) Pub. No.: US 2006/0175711 A1
(43) Pub. Date: Aug. 10, 2006

(54) Structure and method for bonding an IC chip

(75) Inventors: Pao-Yun Tang, Tao-Yuan Hsien (TW); Shu-Lin Ho, Tao-Yuan Hsien (TW); Hsiu-Sheng Hsu, Tao-Yuan Hsien (TW); Nan-Cheng Huang, Tao-Yuan Hsien (TW)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: HannStar Display Corporation, Tao-Yuan Hsien (TW)

(21) Appl. No.: 11/054,693

(22) Filed: Feb. 8, 2005

(51) Int. Cl. H01L 23/48; H01L 21/50

(52) U.S. Cl. 257/782; 257/783; 438/118; 257/E23.026

(57) ABSTRACT

A method for bonding an IC chip to a substrate where the method comprises the steps of providing an IC chip with a plurality of bumps each having a buffer layer and a conductive layer, providing a substrate having a plurality of conductive elements arranged corresponding to the plurality of bumps, placing a non-conductive film between the plurality of conductive devices and their corresponding bumps, and pressing and heating the IC chip and the substrate so that the plurality of bumps are in contact with the plurality of conductive elements respectively. The bonding structure is formed between a first and second substrate where the structure has a buffer layer having an opening and formed on the first substrate, a conductive layer formed on the buffer layer, and a non-conductive film formed between the conductive layer and the second substrate as a bonding medium for the bonding structure.

### BACKGROUND OF THE INVENTION

1. Field of the Invention

The present invention relates to a structure and method for bonding an IC chip. More particularly, the present invention relates to a structure and method for bonding an IC chip using Non-conductive film (NCF).

2. Description of the Related Art

Liquid crystal displays (LCDs) have been widely used in place of cathode ray tubes (CRT) and have become the mainstream of the market nowadays. The manufacturing of the LCDs involves many processes, among which the bonding of IC chips to the LCD panel is one of the most important. Of all the methods used for the process, tape automated bonding (TAB) and chip-on-glass (COG) technologies are the most commonly seen. They may also be used to bond other chips to printed circuit boards (PCBs) or leadframes.

To bond the IC chips onto a glass substrate, manufacturers often use anisotropic conductive film (ACF) as the adhesive medium, because ACF has the characteristic of having anisotropic conductivity. In general practices, the IC chip is bonded by ACF to the glass substrate first through bumps each corresponding to a pin of the IC chip (i.e. the bumps of the IC chip pins are bonded by ACF onto the glass substrate, respectively). However, the use of this material faces considerable difficulties when a product requires that the LCD panel be designed with higher density of pins or bumps on the IC chip. Firstly, the conductive particles within ACF adjacent to bumps have a tendency to bridge the neighboring bumps electrically, thus causing short circuit. Secondly, the horizontal insulation of the ACF is contingent on the pitch of pins or bumps on the IC chip, the density of conductive particles in the ACF, the diameter, as well as the coating, of the conductive particles. Although fine-pitch ACF may be used to alleviate the foregoing problems, a high manufacture cost will be needed.

To solve this problem, some manufacturers use non-conductive film (NCF) to replace ACF. However, experimental evidences show that NCF cannot be used successfully for Au bumps. Attempts have been made to solve the above dilemma. U.S. Pat. No. 6,537,854 discloses a multi-layered bump structure, in which the multi-layered bumps are of a corrugated or serrated shape, and a method of bonding the multi-layered bumps to a substrate to form an ohmic contact. The multi-layered bumps are each so formed with the corrugated or serrated shape that the adhesive material is arranged to present a conductive interface so that the desired contact resistance can be obtained. However, the conductive metal layers formed by photolithography typically has a total thickness of only a few thousand angstroms, which, during the flip chip bonding process, will cause the base film of the conductive metal layers to deform under stress as a result of its low Young's modulus. The conductive layers are thus easy to crack and the resistance and reliability of the contact points of the bumps are insufficient for products. Furthermore, as the base film of each of the multi-layered bumps is made of polymer, its ability to penetrate the oxide layer is lower than that of conventional Au bump, and thus may suffer from the problem of excessively high electrical resistance at the contact points.

Therefore, an improved structure and method for bonding an IC chip are highly desired for current and future LCD products that require high density of IC chip pins bonded onto LCD panel or PCBs.

### SUMMARY OF THE INVENTION

It is an object of the present invention to eliminate the problem of short circuiting or hight cost that comes with conventional bonding technology using ACF or fine pitch ACF as the adhesive material.

It is another object of the present invention to address the problem of the conductive layer being susceptible to cracking and having too high contact point resistance that come with a prior art bonding technolgy using NCF as the adhesive material.

To achieve the above objects, the present invention discloses a method and a structure for bonding an IC chip. The bonding method according to the present invention comprises the steps of providing an IC chip having a plurality of bumps each having a buffer layer and a conductive layer, providing a substrate having a plurality of conductive elements arranged corresponding to the plurality of bumps, placing a non-conductive film between the plurality of conductive devices and their corrsponding bumps, and pressing and heating the IC chip and the substrate so that the plurality of bumps are in contact with the plurality of conductive elements respectively.

The bonding structure according to the present invention is formed between a first substrate and a second substrate; the structure comprises a buffer layer having an opening and formed on the first substrate, a conductive layer formed on the buffer layer, and a non-conductive film formed between the conductive layer and the second substrate as a bonding medium for the bonding structure.

In addtion, a recess formed on the top of said bonding structure has a depth of at least 2 μm for improving the problem of having remnant adhesive material left on the conductive connection interface. And the top of the bonding structure further comprises at least one trough in order to channeling out excessive said adhesive material effectively.

The foregoing is a summary and thus contains, by necessity, simplifications, generalizations, and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The accompanying drawings, which are incorporated into, and constitute a part of, this specification, illustrate one or more embodiments of the present invention and, together with the detailed description, serve to explain the principles and implementations of the invention. The figures are not to scale. In the drawings:

FIG. 1 is a cross-sectional view of a bonding structure according to the present invention;

FIG. 2 is a perspective view of a smart bump according to the present invention;

FIG. 3A is a cross-sectional view of the buffer layer of the smart bump according to the present invention;

FIG. 3B is a top view of the buffer layer of the smart bump according to the present invention;

FIG. 3C is a cross-sectional view of the buffer layer of the smart bump of another embodiment according to the present invention;

FIG. 3D is a top view of the buffer layer of the smart bump of yet another embodiment according to the present invention;

FIG. 4A is a cross-sectional view of the smart bump of type I of the bonding structure of the invention shown in FIG. 2;

FIG. 4B is a cross-sectional view of the smart bump of type II of the bonding structure of the invention shown in FIG. 2;

FIG. 4C is a cross-sectional view of the smart bump of type III of the bonding structure of the invention shown in FIG. 2;

FIG. 4D is a cross-sectional view of the smart bump of type IV of the bonding structure of the invention shown in FIG. 2;

FIG. 4E is a cross-sectional view of the buffer layer of the foregoing smart bumps according to the present invention;

FIG. 4F illustrates stress-strain curves with respect to the conventional Au bump, smart bumps according to the present invention;

FIG. 4G illustrates resistance curves of the conventional Au bump and the smart bump after heating cycle test of COG NCF process;

FIG. 5 is a top view of the smart bump according to the present invention;

FIG. 5A through FIG. 5C are cross-sectional views of the smart bump according to the present invention; and

FIG. 6A through FIG. 6C are top views of the smart bump according to another embodiments of the present invention.

### DETAILED DESCRIPTION OF THE INVENTION

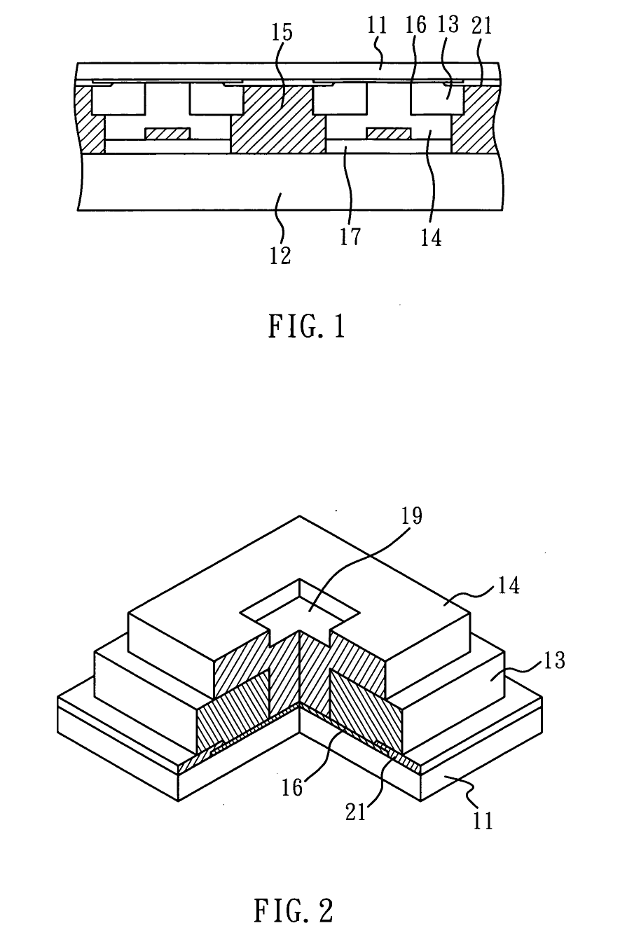

FIG. 1 shows a cross-sectional view of a bonding structure according to the present invention. The bonding structure, placed between a first substrate 11 and a second substrate 12, comprises a buffer layer 13, a conductive layer 14 and an adhesive layer 15. The first substrate 11 is an IC substrate having conductive pads 16 surrounded by an insulating passivation layer 21. The second substrate 12 is a glass substrate having a plurality of conductive elements 17. The conductive layer 14 is formed partially on the buffer layer 13 and conductive pad 16. The adhesive layer 15 is formed between the conductive layer 14 and the second substrate 12 to function as a connection medium to finish the bonding structure. The adhesive layer 15 may be a non-conductive film made of epoxy resin or acrylic resin or any adhesive material.

A bonding method used in conjunction with the bonding structure involves the following steps: First, placing the adhesive layer 15 between the conductive elements 17 and the conductive layer 14. Then, the first and second substrates 11, 12 are pressed and heated to make the conductive layer 14 be in contact with the conductive elements 17. By the bonding structure and method, the conductive pads 16 are electrically connected with the conductive elements 17.

FIG. 2 shows a perspective view of a smart bump of the bonding strcuture acccording to an embodiment of the present invention. As shown in the diagram, on an IC substrate 11 is placed a plurality of condcutive pads 16. The IC substrate 11 may be a substrate supporting a plurality of ICs for driving a LCD and the conductive pads 16 thereon is used for external connection. The conductive pads 16 may be metal pads including aluminum, tungsten, copper and so on, and each pad may be surrounded by a passivation layer 21. The passivation layer 21 may be made of dielectric materials such as silicon nitride or silicon oxide. A buffer layer 13 is formed on the IC substrate 11 and may be made of polymers, such as polyimide. The buffer layer 13 is used mainly to reduce Young's modulus of the bump and further shield the passivation layer 21 against the bonding pressure required for the bonding process as to protect it from cracking. A conductive layer 14 is partially formed on the buffer layer 13 and conductive pad 16 and may be made of metals or metal alloys and formed by electroplating or sputtering. A recess area 19 with a depth about 2 micrometers or larger is formed on the top surface of the conductive layer 14.

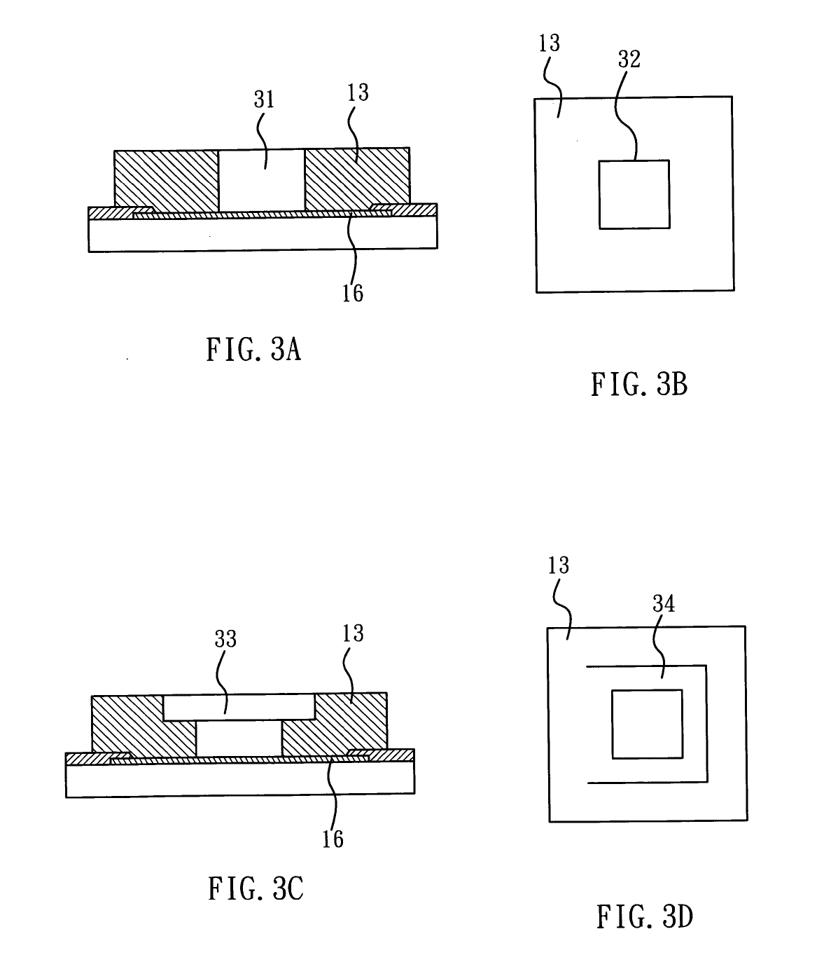

FIG. 3A shows a cross-sectional view of the buffer layer of the smart bump of the bonding strcuture of the present invention. FIG. 3B shows a top view of the buffer layer of the smart bump of the bonding strcuture of the present invention. As shown in the figures, the buffer layer 13 has an opening 31, which may be formed by spin coating, lithography and etching. The opening 31 is formed to communicate with the conductive layer (not shown) thereabove and the conductive pad 16 therebelow. The opening 31 may be shaped like a square 32, a rectangle, a semi-circle, a circle or a polygonal. Besides, at least an opening is formed on the buffer layer 13 to form a better electric connection.

FIG. 3C shows a cross-sectional view of the buffer layer of the smart bump of another embodiment of the present invention. FIG. 3D shows a top view of the buffer layer of the smart bump of another embodiment of the present invention. The buffer layer 13 has an opening 33 formed by a photolithography such as a half-tone process. Viewed from top, the opening 33 is shaped like a frame 34.

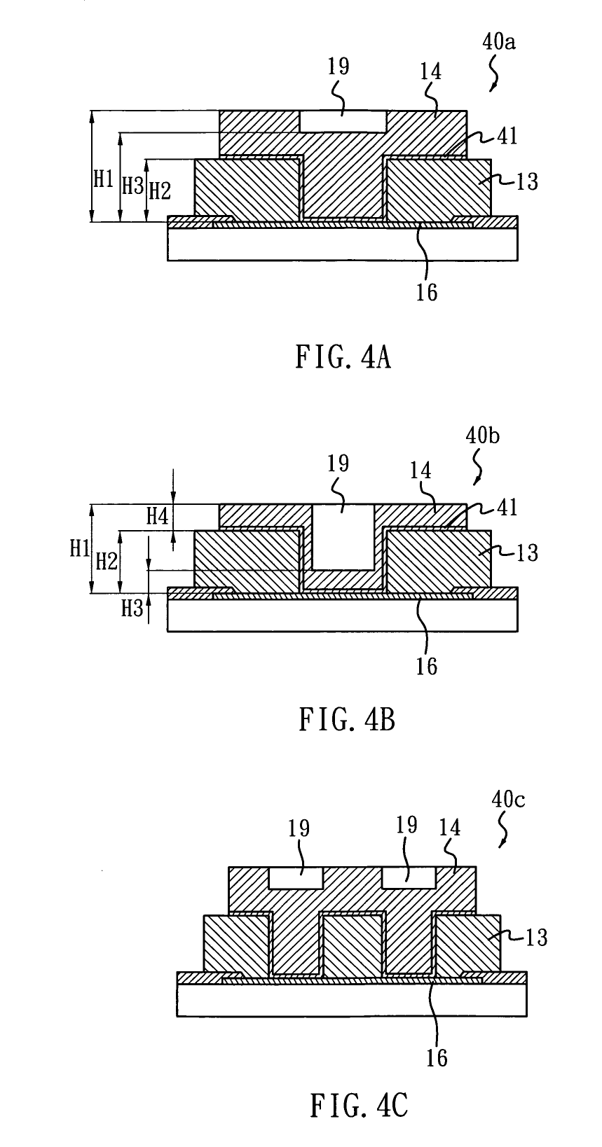

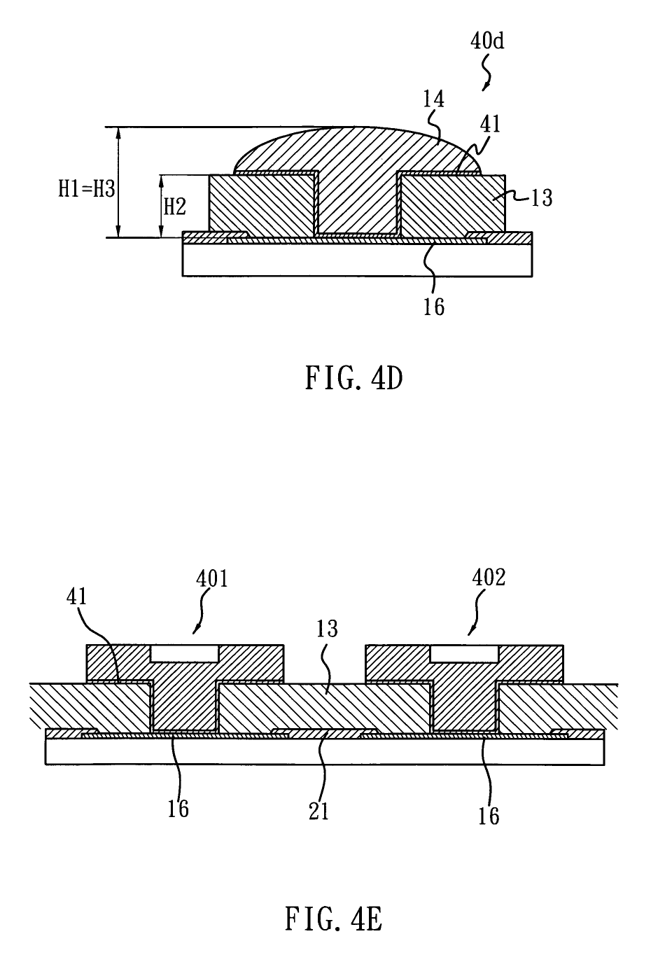

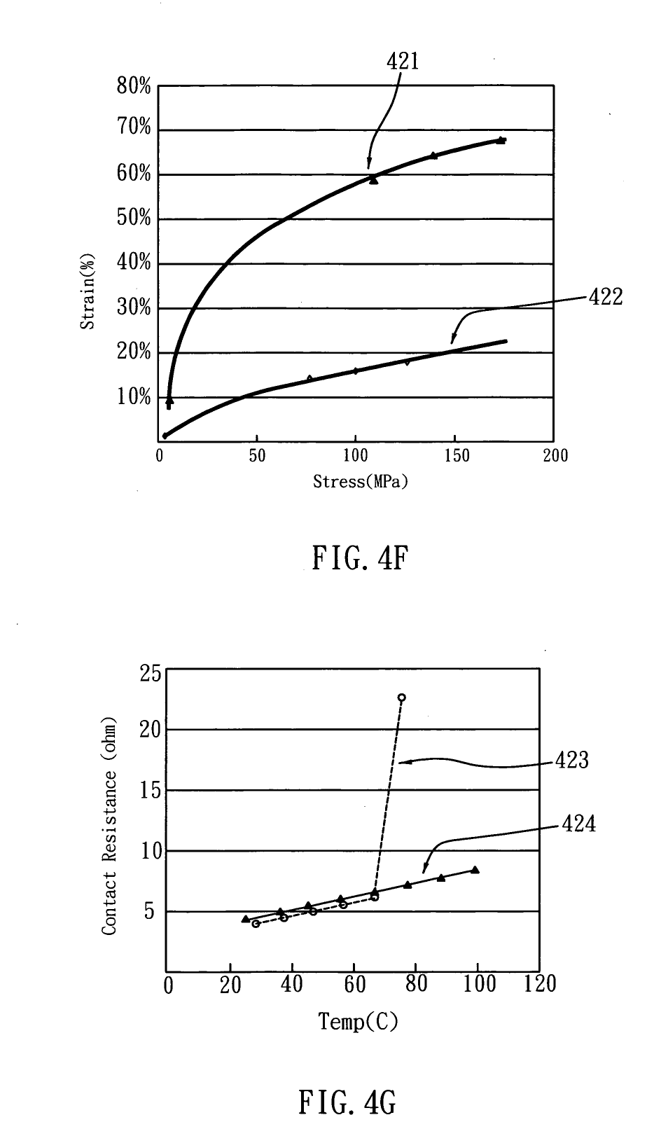

FIG. 4A shows a cross-sectional view of the smart bump of a particular type (hereinafter termed Type I) of the bonding structure according to the present invention. In the bump 40a, a conductive layer 14 is formed on a buffer layer 13 with at least one opening by electroplating or sputtering. And then the conductive layer 14 has a similar profile of said buffer layer and a recess 19 located on the opening of the buffer layer. The conductive layer 14 has a thickness H3 around its recess 19, which is greater than a thickness H2 of the buffer 13 (i.e. H3>H2). And to obtain a better Young's modulus of the bump 40a, the thickness H2 of the buffer layer 13 is at least one-third a thickness H1 of the bump 40a (i.e. H2/H1>=⅓).

FIG. 4B shows a cross-sectional view of the smart bump of another particular type (hereinafter termed Type II) of the bonding structure of the present invention. In the bump 40b, a conductive layer 14 is formed on a buffer layer 13 with at least one opening by sputtering or electroplating. And then the conductive layer 14 has a similar profile of said buffer layer and a recess 19 located on the opening of the buffer layer. The conductive layer 14 has a thickness H3 around its recess 19, which is less than the thickness H2 of the buffer layer 13 (i.e. H3<H2), and substantially equal to a thickness H4 of the conductive layer 14 on the buffer layer 13. Preferably, the thickness H3 is larger than 1 μm so that the conductive layer 14 may not crack during the bonding process. In addition, to let the bump 40b have a better Young's modulus, the thickness H2 is made in proportion to the thickness H1 (i.e. H2/H1>=⅓).

FIG. 4C shows a cross-sectional view of the smart bump of yet another particular type (hereinafter termed Type III) of the bonding structure of the present invention. In the bump 40c, the conductive layer 14 is formed partially on the buffer layer 13 by sputtering or electroplating. The buffer layer 13 has two openings in such as a manner that the conductive layer 14 is shaped like a Π form.

FIG. 4D shows a cross-sectional view of the smart bump of the other particular type (hereinafter termed Type IV) of the bonding structure of the present invention. In the bump 40d, the conductive layer 14 is formed on the buffer layer 13 with at least one opening by electroplating or sputtering. The conductive layer 14 has a thickness H3 on the opening of the buffer layer, which is equal to a thickness H1 of the smart bump 40d and greater than a thickness H2 of the buffer layer 13 (i.e. H3=H1 and H3>H2). To obtain a better Young's modulus of the bump 40d, the thickness H2 of the buffer layer 13 is at least one-third the thickness H1 of the bump 40d (i.e. H2/H1>=⅓).

Referring to FIG. 4E, a different kind of the buffer layer's structure of the foregoing smart bumps of the present invention is depicted therein. In this structure, any two neighboring bumps have a common buffer layer 13 over a common passivation layer 21. In other words, the buffer layer 13 of a first bump 401 and a second bump 402 is not separated during the spin coating, micrography and etching processes.

The foregoing bumps 40a, 40b, 40c, 40d further comprise a multi-layered metal structure 41 located between the buffer layer 13 and the conductive layer 14 and may be made of Al, Ni, Cu, Ag, Au, or a combination of the above including an alloy or a stack. Take a stack multi-layered metal structure for example, it could be of a Ni base coating and Au top coating. And it could also be the stack layers comprising the adhesion film, the wetting film and the conductive film. The main purpose of the adhesion film is to allow the bumps to adhere well to the buffer film 13 and the conductive pad 16. The adhesion film is made from a material such as tungsten, titanium or chromium. The wetting film is made from a material such as nickel or copper. The conductive film such as gold is then formed over the wetting film. The multi-layered metal structure 41 is formed by, for example, sputtering or evaporation. With the multi-layered metal structure 41, a combination structure among the elements of the bumps 40a, 40b, 40c and 40d may be mechanically enhanced.

Referring to FIG. 4F, stress-strain curves with respect to the conventional Au bump and the smart bump of the invnetion are shown therein. The curve 421 in FIG. 4F indicates the measured coefficients of strain -stress of the smart bump according to the present invention, and the curve 422 indicates the measured coefficients of strain-stress of the conventional Au bump. By this drawing, it may be known that the smart bump under an identical pressure of 100 MPa, has a strain amount of 60% while the conventional Au bump has a strain amount of approximately 15%. The smart bump has at least four times strained amount as compared to that of the conventional Au bump. That is to say that the smart bump has a better compressive resistance compared to the conventional Au bump. Thus the thickness of the smart bump is reduced to 9 um, it is still enough for compensation of height difference caused from the bumping process and thus promotes a yield of the COG bonding process.

Referring to FIG. 4G, results of a heating cycles test with respect to the conventional Au bump and the smart bump after the COG NCF process. Under the different heating temperature, the resistance of the conventional Au bump is shown in the curve 423 and the resistance of the smart bump is shown in curve 424. Through this drawing, it may be known that an unstable contact resistance and even an open circuit occur when the temperature is greater than 80° C. in the conventional Au bump owing to the mismatched thermal expansion coefficients between the Au bump and the ACF. On the other hand, contact resistance of the smart bump is stable even when the temperature is rapidly increased from 20° C. to 100° C.

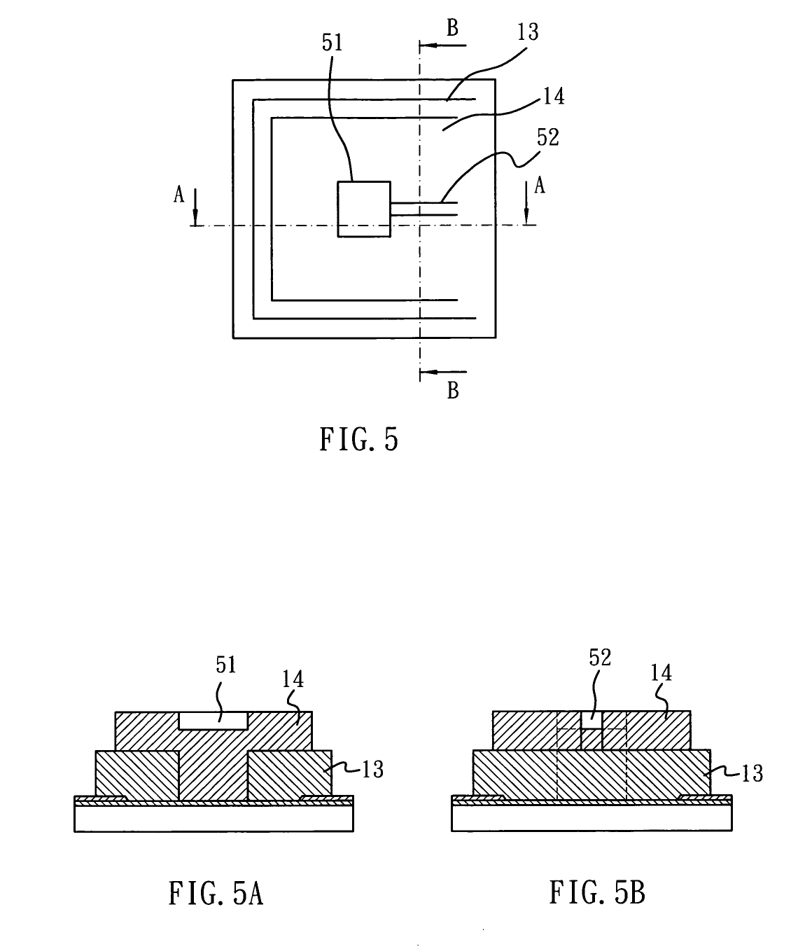

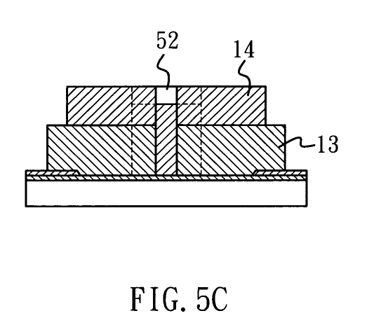

FIG. 5 is a top view of the smart bump of another embodiment according to the present invention. For the sake of keeping overflowing adhesive material from remaining in the conductive interface of the bonding structure, which may causes poor contact of the conductive interface, a recess 51, which preferrably have a depth of about 2 μm or larger, is provided to the conductive layer 14 as shown in FIG. 5A. In addition, at least a trough 52 is formed on top of the smart bump for channeling excessive said adhesive material out effectively. In one option, a trough 52 may be formed on the conductive layer 14 as shown in FIG. 5B. As yet another option, a trough 52 may be formed on the conductive layer 14 and the buffer layer 13 as shown in FIG. 5C. The depths of the recess 51 and the troughs 52, 52′ may vary according to necessity and are processed by etching.

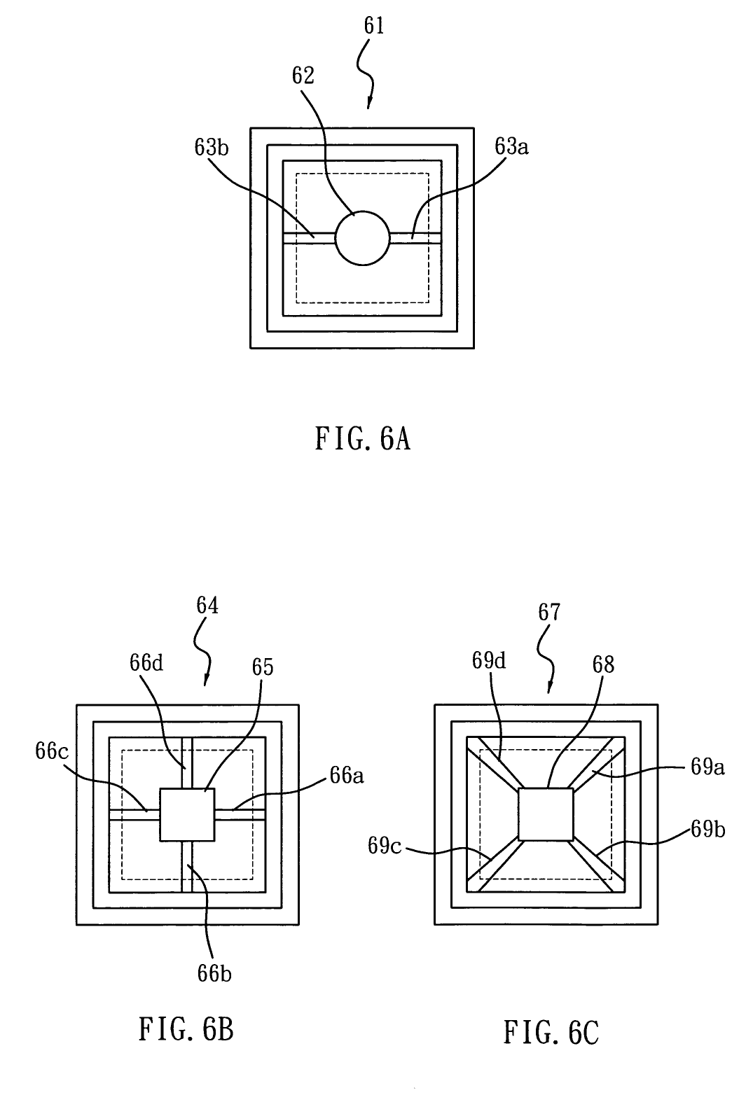

FIG. 6A through 6C show cross-sectional views of the smart bump according to another embodiments of the present invention. As shown in FIG. 6A, a bump 61 is provided with a circular recess 62 and two troughs 63a, 63b. As shown in FIG. 6B, a bump 64 is provided with a square recess 65 and four troughs 66a-66d, wherein each of the troughs 66a-66d extends perpendicuclarly to one side of the square recess 65. As shown in FIG. 6C, a bump 67 is provided with a square recess 68 and four troughs 69a-69d, wherein each of the troughs 69a-69d extends along diagonals of the square recess 68 and outside of the square recess 68. Based on the above-mentioned structures which channeling out the adhesive material, the recess 68 may be shaped like a square, a rectangle, a circle, a polygonal, a frame. And in accordance with the situation, the smart bump has one or more troughs which may be designed in direction, position and shape.

Since NCF may be used for the bonding structures and the bonding method of the invention, the problems of short circuit and increased cost due to the use of ACF in conventional bonding structure have been eliminated. In addition, since the bumps of the invention have been designed to optimize Young's modulus and the thickness of conductive layer compared to that of conventional Au bump, both the problems of conductive layer cracking during the bonding process and excessively resistance at the contact points that have been plaguing conventional bonding structures are avoided. Furthermore, since a recess connected with and without troughs has been provided on top of the bump structures of present invention, the problem of overflowing NCF material to cause excessively high contact resistance at the bonding interfaces has been avoided.

While this invention has thus far been described in connection with the preferred embodiments thereof, it will readily be possible for those skilled in the art to put this invention into practice in various other manners without departing from the scope set forth in the appended claims.

What is claimed is:

1. A bonding structure for bonding an IC chip, wherein said bonding structure formed between a first substrate and a second substrate, comprising:
a buffer layer having an opening and formed on said first substrate, wherein a thickness ratio of said buffer layer to said bonding structure is at least about ⅓;
a conductive layer formed on said buffer layer; and
a non-conductive film formed between said conductive layer and said second substrate as a bonding medium for said bonding structure.

2. The bonding structure as claimed in claim 1, wherein said conductive layer formed on the opening of said buffer layer has a thickness greater than said buffer layer.

3. The bonding structure as claimed in claim 1, wherein the shape of said opening can be circular, rectangular, polygonal, or like a frame.

4. The bonding structure as claimed in claim 1, which further comprises a multi-layered metal structure formed between said buffer layer and said conductive layer.

5. The bonding structure as claimed in claim 1, wherein said non-conductive film is made of epoxy resin or acrylic resin.

6. The bonding structure as claimed in claim 1, which further comprises at least a trough formed on said conductive layer.

7. The bonding structure as claimed in claim 1, which further comprises at least a trough formed on said conductive layer and said buffer layer.

8. The bonding structure as claimed in claim 1, wherein the thickness of said conductive layer on the opening of said buffer layer is thinner than the thickness of said buffer layer.

9. The bonding structure as claimed in claim 8, wherein said conductive layer has a thickness greater than 1 μm.

10. A bonding structure for bonding an IC chip, wherein said bonding structure formed between a first substrate and a second substrate, comprising:
a buffer layer having an opening and formed on said first substrate;
a conductive layer having a recess and formed on said buffer layer, wherein said recess has a depth of at least 2 μm; and
an adhesive material formed between said conductive layer and said second substrate as a bonding medium for said bonding structure.

11. The bonding structure as claimed in claim 10, wherein the shape of said opening can be circular, rectangular, polygonal, or like a frame.

12. The bonding structure as claimed in claim 10, which further comprises a multi-layered metal structure formed between said buffer layer and said conductive layer.

13. The bonding structure as claimed in claim 10, which further comprises at least a trough formed on said conductive layer for channeling out excessive said adhesive material.

14. The bonding structure as claimed in claim 10, which further comprises at least a trough formed on said conductive layer and the buffer layer for channeling out excessive said adhesive material.

15. The bonding structure as claimed in claim 10, wherein a thickness ratio of said buffer layer to said bonding structure is at least about ⅓.

16. A method for bonding an IC chip having bumps to a substrate, comprising:
providing said IC chip, wherein said bumps have a conductive layer and a buffer layer having an opening filled with said conductive layer and a thickness ratio of said buffer layer to said bonding structure is at least about ⅓;
providing said substrate having a plurality of conductive elements arranged correspondingly to said bumps;
placing a non-conductive film between said plurality of conductive elements and said bumps; and
pressing and heating said IC chip and said substrate to contact said bumps with said plurality of conductive elements.

17. The method as claimed in claim 16, wherein the shape of said opening can be circular, rectangular, polygonal, or like a frame.

18. The method as claimed in claim 16, which further comprises a step of forming a multi-layered metal structure between said buffer layer and the conductive layer.

19. The method as claimed in claim 18, wherein said multi-layered metal structure is made of at least a metal, which includes Al, Ni, Cu, Ag, Au, or a combination of the above.

20. The method as claimed in claim 18, which further comprises a step of forming said conductive layer by a Ni based coating and an Au top coating.

21. The method as claimed in claim 16, wherein said non-conductive film includes epoxy resin or acrylic resin.

22. The method as claimed in claim 16, which further comprises a step of forming a trough on said conductive layer.

23. The method as claimed in claim 22, which further comprises a step of etching out said trough.

24. The method as claimed in claim 16, which further comprises a step of forming a trough on said conductive layer and said buffer layer.
